(19) United States
(12) Patent Application Publication
(10) Pub. No.: US 2023/0072827 A1
(43) Pub. Date: Mar. 9, 2023

(54) TRENCH GATE SILICON CARBIDE MOSFET WITH HIGH RELIABILITY

(71) Applicant: ZJU-Hangzhou Global Scientific and Technological Innovation Center, Hangzhou (CN)

(72) Inventors: Kuang SHENG, Hangzhou (CN); Na REN, Hangzhou (CN); Chaobiao LIN, Hangzhou (CN)

(21) Appl. No.: 17/903,029

(22) Filed: Sep. 5, 2022

(30) Foreign Application Priority Data
Sep. 7, 2021 (CN) 202111044550.X

(51) Int. Cl. H01L 29/78; H01L 29/16; H01L 29/06; H01L 29/10

(52) U.S. Cl. CPC H01L 29/7813; H01L 29/1608; H01L 29/063; H01L 29/1095

(57) ABSTRACT

A trench gate silicon carbide MOSFET with high reliability, including: An N+ type substrate, an N− type drift region, a first P type region, a P+ type contact region, an N+ type contact region, an N type equivalent resistance region between the first P type region and the N+ type contact region, a gate dielectric layer, a trench gate, an isolation dielectric layer, a source electrode and a drain electrode.

### CROSS-REFERENCE TO RELATED APPLICATIONS

The present disclosure claims the priority of Chinese Patent Application No. 202111044550. X, filed to the China National Intellectual Property Administration on Sep. 7, 2021 and entitled “a trench gate silicon carbide MOSFET with high reliability”, which is incorporated herein its entirety by reference.

### TECHNICAL FIELD

The present disclosure generally relates to semiconductor devices, and more particularly but not exclusively relates to a trench gate silicon carbide (SIC) MOSFET (Metal-Oxide-Semiconductor Field-Effect Transistor) with high reliability.

### BACKGROUND

As a wide band gap semiconductor material, silicon carbide (SiC) has advantages of high breakdown electric field, high saturated electron mobility and high thermal conductivity. Therefore, SIC power semiconductor devices can be used in the applications of high voltage, high power, high frequency and high temperature, which can improve the efficiency of power electronic devices and reduce the volume and weight of devices. Compared with traditional silicon-based devices, SIC power semiconductor devices have more advantages.

Silicon carbide MOSFET is one of the new wide band gap power semiconductor devices. Compared with Si MOSFETs or Si IGBT, SIC MOSFETs have lower on-resistance and faster switching speed. Compared with planar MOSFETs, trench gate MOSFETs have better channel utilization and can eliminate a resistance caused by JFET region, but a deep trench etching technology has great challenges. A morphology of etched surface, including etching depth, etching vertical angle, roughness of etched side wall, all have great influence on device performances. FIG. 0.1 schematically shows a cross-sectional view of a conventional trench gate MOSFET cell, including an N+ type substrate 1, a drain electrode 13 formed below the N+ type substrate 1, an N− type drift region 2 formed above the N+ type substrate 1, a trench gate region 6, a gate dielectric layer 7, and a first P type region 3 formed above the N− type drift region 2, an N+ type contact region 4 formed above the first P type region 3, a source electrode 14 formed above the N+ type contact region 4, an isolation dielectric region 15 formed above the trench gate region 6, and a P+ type contact region 5 which locates in and penetrates the N+ type contact region 4 and extends to the first P type region 3.

In an actual circuit, there are two kinds of short circuit faults. One fault is that when a device works normally, the load is suddenly short circuited, and the device quickly changes from normal working state to high voltage and high current working state. Another fault is that when an initial state of the device is off and the load has been short circuited, a turn-on signal is suddenly given to the device, and the device quickly jumps from zero current state to high current state. When the device is short circuited, a large current will generate high heat. Because of a small area and small on-resistance of trench gate MOSFET, it will produce greater short-circuit current, which poses a severe challenge to a reliability of the device.

### SUMMARY

It is an object of the present disclosure to provide a SiC trench MOSFET with high reliability.

An embodiment of the present disclosure is directed to a trench gate silicon carbide MOSFET with high reliability, including an N+ type substrate, a drain electrode below the N+ type substrate, an N− type drift region above the N+ type substrate, a gate dielectric layer, a trench gate region, a first P type region above the N− type drift region, an N type equivalent resistance region above the first P type region, an N+ type contact region above the N type equivalent resistance region, a source electrode above the N+ type contact region, an isolation dielectric region above the trench gate region, and a P+ type contact region penetrating through the N+ type contact region and the N type equivalent resistance region and extending to the first P type region. The gate dielectric layer is formed around the trench gate region and in the N− type drift region. The P+ type contact region penetrates the N+ type contact region, the N type equivalent resistance region and the first P type region and extends to the N− type drift region.

The present disclosure can decrease a saturation current, improving a short-circuit time and short-circuit withstand energy of a device without reducing static characteristics. The present disclosure is feasible in laboratories and industrial manufacture, promising a good application prospect.

### BRIEF DESCRIPTION OF THE DRAWINGS

The present disclosure can be further understood with reference to the following detailed description and the appended drawings, and like elements are provided with like reference numerals. The drawings are only for illustration purpose. They may only show part of the devices and are not necessarily drawn to scale.

FIG. 1 schematically shows a cross-sectional view of a conventional trench gate silicon carbide MOSFET cell.

FIG. 2 schematically shows a cross-sectional view of a trench gate silicon carbide MOSFET with high reliability of the present disclosure.

FIG. 3 schematically shows the equivalent current path diagram of the embodiment 1 at forward conduction.

FIG. 4 schematically shows a cross-sectional view of the embodiment 2 of the present invention.

FIG. 5 schematically shows a cross-sectional view of the embodiment 3 of the present invention.

FIG. 6 schematically shows a cross-sectional view of the embodiment 4 of the present invention.

FIG. 7 schematically shows a cross-sectional view of the embodiment 5 of the present invention.

FIG. 8 schematically shows a cross-sectional view of the embodiment 6 of the present invention.

FIG. 9 schematically shows a cross-sectional view of the embodiment 7 of the present invention.

FIG. 10 schematically shows a cross-sectional view of the embodiment 8 of the present invention.

FIG. 11 schematically shows a cross-sectional view of the embodiment 9 of the present invention.

FIG. 12 schematically shows a cross-sectional view of the embodiment 10 of the present invention.

FIG. 13 schematically shows a cross-sectional view of the embodiment 11 of the present invention.

FIG. 14 schematically shows the equivalent current path diagram of the embodiment 11 at forward conduction.

FIG. 15 schematically shows a cross-sectional view of the embodiment 12 of the present invention.

FIG. 16 schematically shows a cross-sectional view of the embodiment 13 of the present invention.

FIG. 17 schematically shows a cross-sectional view of the embodiment 14 of the present invention.

FIG. 18 schematically shows a cross-sectional view of the embodiment 15 of the present invention.

FIG. 19 schematically shows a cross-sectional view of the embodiment 16 of the present invention.

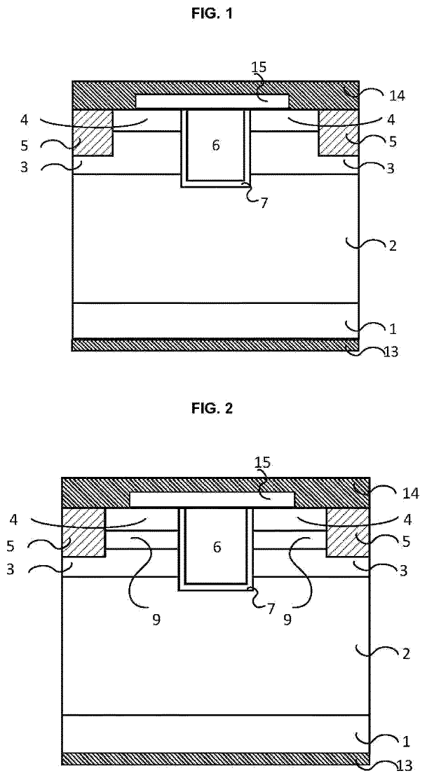

### DETAILED DESCRIPTION OF THE EMBODIMENTS

Reference will now be made in detail to the preferred embodiments of the disclosure, examples of which are illustrated in the accompanying drawings. While the disclosure will be described in conjunction with the preferred embodiments, it will be understood that they are not intended to limit the disclosure to these embodiments. On the contrary, the disclosure is intended to cover alternatives, modifications and equivalents, which may be included within the spirit and scope of the disclosure as defined by the appended claims. Furthermore, in the following detailed description of the present disclosure, numerous specific details are set forth in order to provide a thorough understanding of the present disclosure. However, it will be obvious to one of ordinary skill in the art that the present disclosure may be practiced without these specific details. In other instances, well-known methods, procedures, components, and circuits have not been described in detail so as not to unnecessarily obscure aspects of the present disclosure.

### Embodiment 1

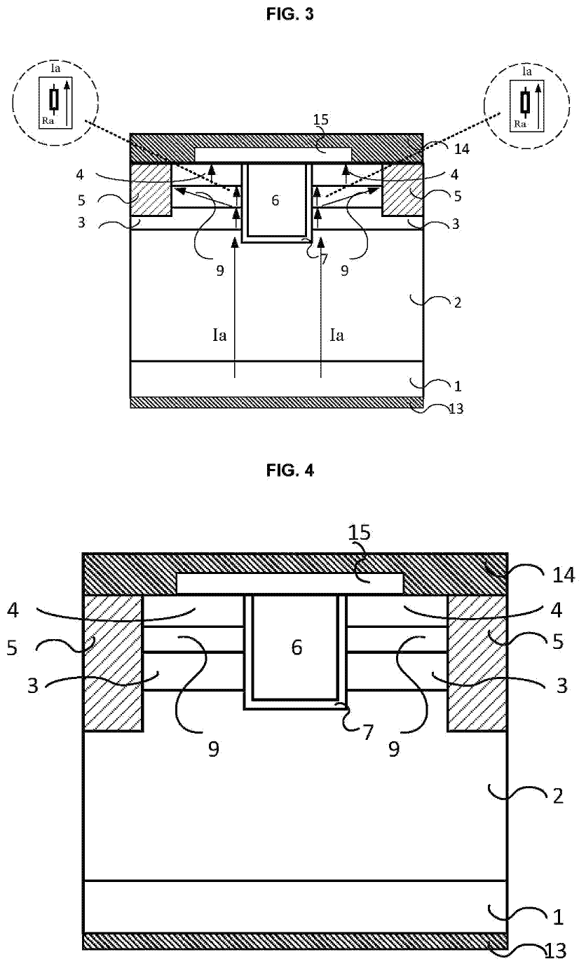

FIG. 2 schematically shows a cross-sectional view of a trench gate silicon carbide MOSFET with high reliability of the present disclosure. It includes an N+ type substrate 1, a drain electrode 13 formed below the N+ type substrate 1, an N− type drift region 2 formed above the N+ type substrate 1, a gate dielectric layer 7, a trench gate region 6, a first P type region 3 formed above the N− type drift region 2, an N type equivalent resistance region 9 formed above the first P type region 3, an N+ type contact region 4 formed above the N type equivalent resistance region 9, a source electrode 14 formed above the N+ type contact region 4, an isolation dielectric region 15 formed above the trench gate region 6, and a P+ type contact region 5 penetrating the N+ type contact region 4 and the N type equivalent resistance region 9 and extending to the first P type region 3. The trench gate region 6 penetrates the N+ type contact region 4, the N type equivalent resistance region 9, the first P type region 3 and extends to the N− type drift region 2. The gate dielectric layer 7 is formed around the trench gate region 6 and a part of the gate dielectric layer is formed in the N− type drift region 2. The P+ type contact region 5 penetrates the N+ type contact region 4, the N type equivalent resistance region 9 and extends to the first P type region 3. A doping concentration of the N type equivalent resistance region 9 is greater than that of the N− type drift region and less than that of the N+ type contact region. When the device works in the on state, a positive bias voltage is applied to the gate dielectric layer 7, which will induce an electron inversion layer in the first P type region 3. After a forward voltage is applied between the drain electrode and the source electrode, the current Iₐ reaches the source electrode through the N+ type substrate 1 the N− type drift region 2, the channel in the first P type region 3, the N type equivalent resistance region 9 and the N+ contact region 4. The equivalent current path is shown in FIG. 3, in which the N type equivalent resistance region 9 can be equivalent to the resistance Rₐ. When the device is short circuited, due to the existence of N type equivalent resistance region 9, the saturation current of the device can be reduced, the short-circuit ability of the device is improved, and the reliability of the device is enhanced.

The N+ type substrate 1 can be 4H—SiC or 6H—SiC.

The trench gate region 6 can be N-type or P-type doped polysilicon, or metal like nickel, tungsten, or compound like titanium nitride.

The source electrode 14 and the drain electrode 13 can be metal like copper, aluminum, nickel and titanium.

### Embodiment 2

As shown in FIG. 4, the device structure of this embodiment is different from that of embodiment 1 in that the P+ type contact region 5 penetrates the N+ type contact region 4, the N type equivalent resistance region 9 and the first P type region 3 and extends to the N− type drift region 2.

### Embodiment 3

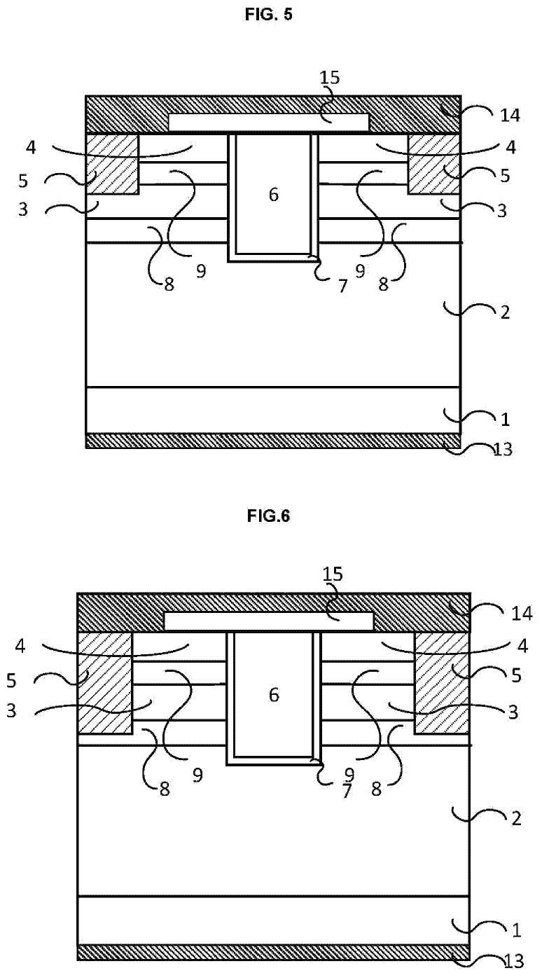

As shown in FIG. 5, the device structure of this embodiment is different from that of embodiment 1 in that a current diffusion region 8 exists between the first P type region 3 and the N− type drift region 2, and the current diffusion region 8 has a small area, which is only distributed on the sidewall of the gate dielectric layer 7, but not at the bottom of the gate dielectric layer 7. The advantage of this structure is that, in the forward conduction state, the current diffusion region 8 can diffuse the current and reduce the on-resistance of the device due to its high doping concentration.

### Embodiment 4

As shown in FIG. 6, the device structure of this embodiment is different from that of embodiment 3 in that the P+ type contact region 5 penetrates the N+ type contact region 4, the N type equivalent resistance region 9 and the first P type region 3 and extends to the current diffusion region 8.

### Embodiment 5

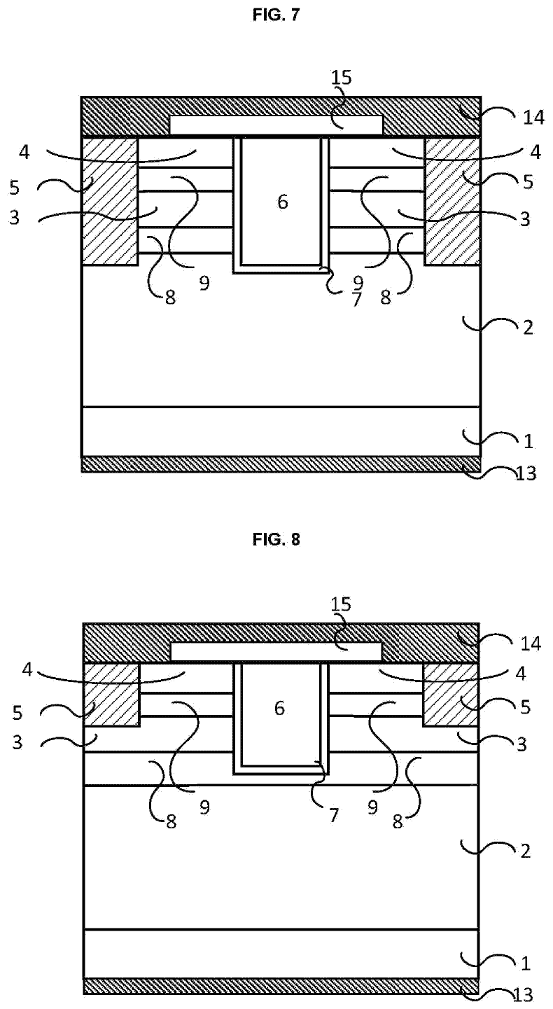

As shown in FIG. 7, the device structure of this embodiment is different from that of embodiment 4 in that the P+ type contact region 5 penetrates the N+ type contact region 4, the N type equivalent resistance region 9, the first P type region 3 and the current diffusion region 8 and extends to N− type drift region 2.

### Embodiment 6

As shown in FIG. 8, the device structure of this embodiment is different from that of embodiment 3 in that the current diffusion region 8 has a large area and is distributed at the side wall of the gate dielectric layer 7 and the bottom of the gate dielectric layer 7. The advantage of this is that it can further reduce the on resistance of the device.

### Embodiment 7

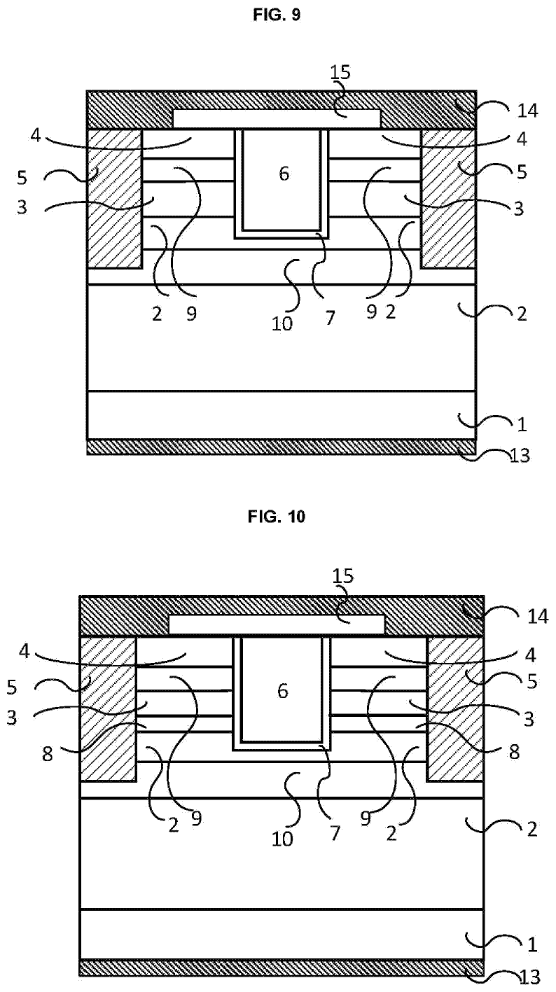

As shown in FIG. 9, the device structure of this embodiment is different from that of embodiment 1 in that the P+ type contact region 5 penetrates the N+ type contact region 4, the N type equivalent resistance region 9 and the first P type region 3 and extends to the N− type drift region 2, and a second N type region 10 is arranged between the P+ type contact region 5 and the N− drift area 2. The advantage of this is that in the blocking state, the breakdown point occurs at the junction of the P+ type contact region 5 and the second N type region 10, which can effectively prevent the breakdown or degradation of the gate dielectric layer and protect the gate dielectric layer.

### Embodiment 8

As shown in FIG. 10, the device structure of this embodiment is different from that of embodiment 1 in that the P+ type contact region 5 penetrates the N+ type contact region 4, the N type equivalent resistance region 9 and the first P type region 3 and extends to the N− type drift region 2. There is an current diffusion region 8 between the first P type region 3 and the N− type drift region 2. The current diffusion region 8 has a small area and is only distributed at the side wall of the gate dielectric layer 7, not at the bottom of the gate dielectric layer 7. A second N type region 10 is arranged between the P+ type contact region 5 and the N− type drift region 2.

### Embodiment 9

As shown in FIG. 11, the device structure of this embodiment is different from that of embodiment 1 in that a P+ type shielding layer 11 is arranged at the bottom of the gate dielectric layer 7. The P+ type contact region 5 can only pass through the N+ type contact region 4, the N type equivalent resistance region 9, the first P type region 3, or extend to the N− type drift region 2. The advantage of this is that in the blocking state, the P+ type shielding layer 11 can shield the electric field at the bottom of the gate dielectric layer 7 to reduce the electric field at the corner of the gate dielectric layer 7 and protect the gate dielectric layer 7.

### Embodiment 10

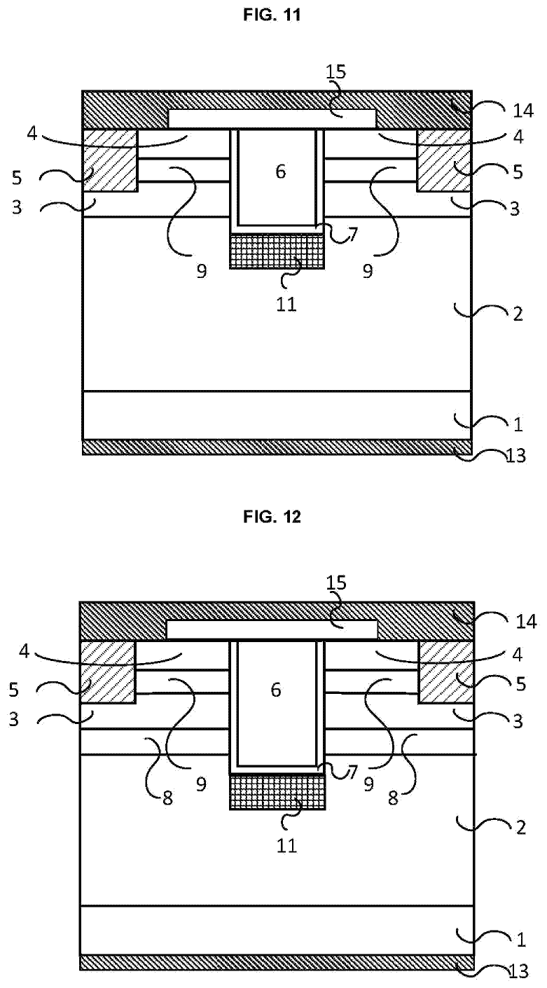

As shown in FIG. 12, the device structure of this embodiment is different from that of embodiment 9 in that there is a current diffusion region 8 between the first P type region 3 and the N− type drift region 2. The current diffusion region 8 can be distributed only at the side wall of the gate dielectric layer 7, or at the side wall and bottom of the gate dielectric layer 7.

### Embodiment 11

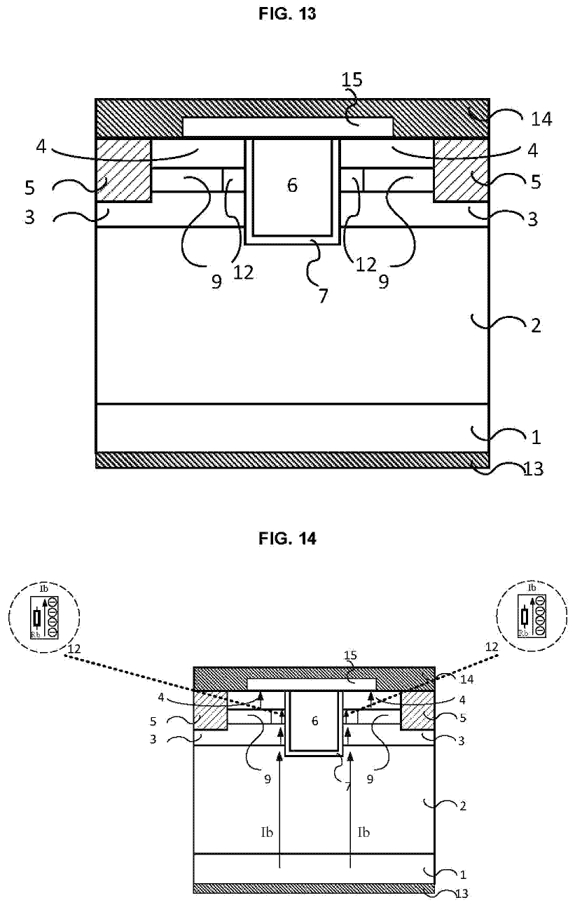

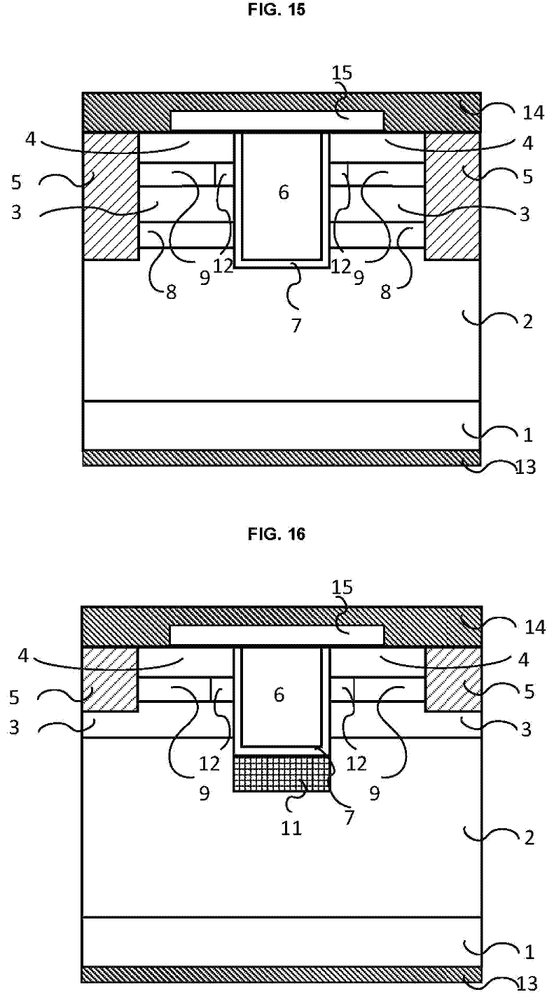

As shown in FIG. 13, the device structure of this embodiment is different from that of embodiment 1 in that a second P type region 12 is added between the gate dielectric layer 7 and the N type equivalent resistance region 9. The P+ type contact region 5 can only penetrate the N+ type contact region 4, the N type equivalent resistance region 9, the first P type region 3, or extend to the N− type drift region 2. The doping concentration of the N type equivalent resistance region 9 is greater than that of the N− type drift region and less than that of the N+ type contact region. The doping concentration of the second P type region is greater than that of the N− type drift region. The second P type region 12 is formed at the vertical side wall of the trench gate region 6 and is in contact with the first P type region 3. The equivalent current path of the device when conducting in the forward direction is shown in FIG. 14, in which the second P type region 12 can be equivalent to resistance R_{b}. The advantage of this is that when the device is short circuited, the current I_{b} will flow to the source through the electron inversion layer induced by the second P type region 12, which will reduce the saturation current of the device and improves its short-circuit ability.

### Embodiment 12

As shown in FIG. 15, the device structure of this embodiment is different from that of embodiment 11 in that there is a current diffusion region 8 between the first P type region 3 and the N− type drift region 2. The current diffusion region 8 can be distributed only at the side wall of the gate dielectric layer 7, or at the side wall and bottom of the gate dielectric layer 7.

### Embodiment 13

As shown in FIG. 15, the device structure of this embodiment is different from that of embodiment 11 in that a P+ type shielding layer 11 is arranged at the bottom of the gate dielectric layer 7.

### Embodiment 14

As shown in FIG. 17, the device structure of this embodiment is different from that of embodiment 13 in that there is a current diffusion region 8 between the first P type region 3 and the N− type drift region 2. The current diffusion region 8 can be distributed only at the side wall of the gate dielectric layer 7, or at the side wall and bottom of the gate dielectric layer 7.

### Embodiment 15

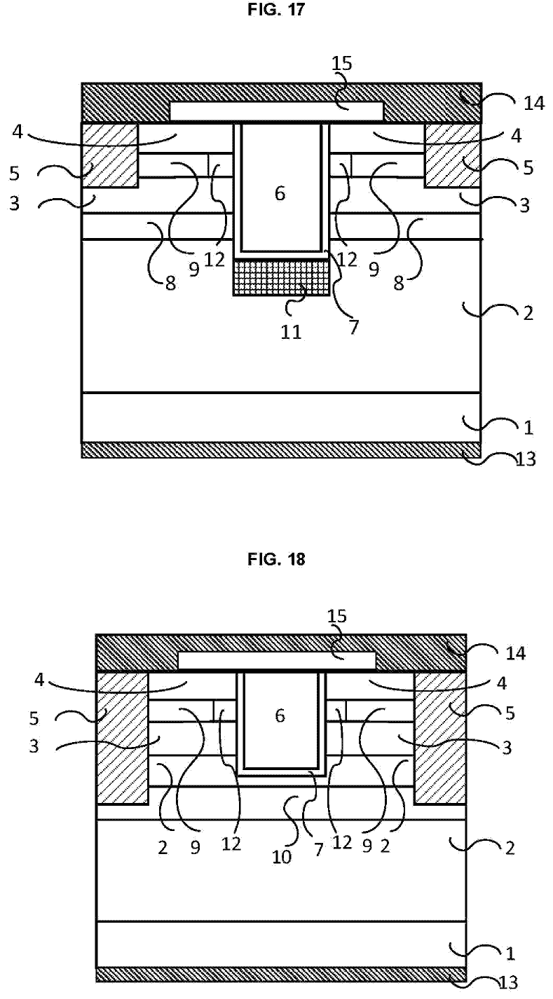

As shown in FIG. 18, the device structure of this embodiment is different from that of embodiment 11 in that the P+ type contact region 5 penetrates the N+ type contact region 4, the N type equivalent resistance region 9 and the first P type region 3 and extends to the N− type drift region 2, and a second N type region 10 is arranged between the P+ type contact region 5 and the N− drift area 2.

### Embodiment 16

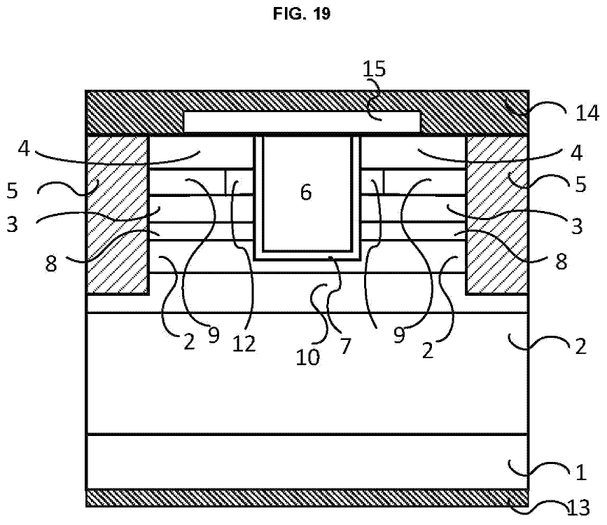

As shown in FIG. 19, the device structure of this embodiment is different from that of embodiment 15 in that a current diffusion region 8 exists between the first P type region 3 and the N− type drift region 2, and the current diffusion region 8 has a small area, which is only distributed on the sidewall of the gate dielectric layer 7, but not at the bottom of the gate dielectric layer 7. The P+ type contact region 5 penetrates the N+ type contact region 4, the N type equivalent resistance region 9, the first P type region 3 and the current diffusion region 8 and extends to N− type drift region 2.

A person skilled in the art should know the above said N-type and P-type are not limited the only doping type, e.g. the present N-type can be P-type, and the present P-type can be N-type in other embodiments.

Obviously, many modifications and variations of the present disclosure are possible in light of the above teachings. It is therefore to be understood that within the scope of the appended claims the disclosure can be practiced otherwise than as specifically described. It should be understood, of course, the foregoing disclosure relates only to a preferred embodiment (or embodiments) of the disclosure and that numerous modifications can be made therein without departing from the spirit and the scope of the disclosure as set forth in the appended claims. Various modifications are contemplated and they obviously will be resorted to by those skilled in the art without departing from the spirit and the scope of the disclosure as hereinafter defined by the appended claims as only a preferred embodiment(s) thereof has been disclosed.

What is claimed is:

1. A trench gate silicon carbide MOSFET with high reliability, comprising:
an N+ type substrate;
a drain electrode formed below the N+ type substrate;
an N− type drift region formed above the N+ type substrate;
a trench gate region;
a gate dielectric layer;
a first P type region formed above the N− type drift region;
an N type equivalent resistance region formed above the first P type region;
an N+ type contact region formed above the N type equivalent resistance region;
a source electrode formed above the N+ type contact region;
an isolation dielectric region formed above the trench gate region;
a P+ type contact region penetrating the N+ type contact region, the N type equivalent resistance region and extending to the first P type region.

2. The trench gate silicon carbide MOSFET according to claim 1, wherein the P+ type contact region is configured to penetrate the N+ type contact region, the N type equivalent resistance region, the first P type region and extend to the N− type drift region.

3. The trench gate silicon carbide MOSFET according to claim 1, wherein a doping concentration of the N type equivalent resistance region is greater than a doping concentration of the N− type drift region and less than a doping concentration of the N+ type contact region.

4. The trench gate silicon carbide MOSFET according to claim 1, further comprising: a current diffusion region between the first P type region and the N− type drift region.

5. The trench gate silicon carbide MOSFET according to claim 4, the P+ type contact region is configured to penetrate the N+ type contact region, the N type equivalent resistance region and the first P type region and extend to the current diffusion region.

6. The trench gate silicon carbide MOSFET according to claim 4, the P+ type contact region is configured to penetrate the N+ type contact region and the N type equivalent resistance region, the first P type region, the current diffusion region and extend to the N− type drift region.

7. The trench gate silicon carbide MOSFET according to claim 4, wherein the current diffusion region is only formed on side walls of the gate dielectric layer and is not formed at a bottom of the gate dielectric layer.

8. The trench gate silicon carbide MOSFET according to claim 4, wherein a doping concentration of the current diffusion region is greater than a doping concentration of the N− type drift region and less than a doping concentration of an N+ type contact region.

9. The trench gate silicon carbide MOSFET according to claim 1, further comprising: a second N type region between the P+ type contact region and the N− type drift region.

10. The trench gate silicon carbide MOSFET according to claim 9, wherein a doping concentration of the second N type region is greater than a doping concentration of the N− type drift region.

11. The trench gate silicon carbide MOSFET according to claim 1, further comprising: a P+ type shielding layer formed at a bottom of the gate dielectric layer.

12. The trench gate silicon carbide MOSFET according to claim 11, a doping concentration of the P+ type shielding layer is less than a doping concentration of the P+ type contact region and greater than a doping concentration of the first P type region.

13. The trench gate silicon carbide MOSFET according to claim 1, further comprising: a second P type region formed between the gate dielectric layer and the N type equivalent resistance region; and a P+ type shielding layer formed at a bottom of the gate dielectric layer.

14. The trench gate silicon carbide MOSFET according to claim 13, a doping concentration of the P+ type shielding layer is less than a doping concentration of the P+ type contact region and greater than a doping concentration of the second P type region.

15. A trench gate silicon carbide MOSFET with high reliability, comprising:
an N+ type substrate;
a drain electrode formed below the N+ type substrate;
an N− type drift region formed above the N+ type substrate;
a trench gate region;
a gate dielectric layer;
a first P type region formed above the N− type drift region;
an N type equivalent resistance region formed above the first P type region;
an N+ type contact region formed above the N type equivalent resistance region;
a source electrode formed above the N+ type contact region;
an isolation dielectric region formed above the trench gate region;
a P+ type contact region penetrating the N+ type contact region, the N type equivalent resistance region and extending to the first P type region;
a second P type region between the gate dielectric layer and the N type equivalent resistance region;
a doping concentration of the N type equivalent resistance region is greater than a doping concentration of the N− type drift region and less than a doping concentration of the N+ type contact region;
a doping concentration of the second P type region is greater than the doping concentration of the N− type drift region.

16. The trench gate silicon carbide MOSFET according to claim 15, wherein the second P type region is formed at vertical sidewalls of a trench gate and is in contact with the first P type region.

17. A trench gate silicon carbide MOSFET with high reliability, comprising:
an N+ type substrate;
a drain electrode formed below the N+ type substrate;
an N− type drift region formed above the N+ type substrate;
a trench gate region;
a gate dielectric layer;
a first P type region formed above the N− type drift region;
an N type equivalent resistance region formed above the first P type region;
an N+ type contact region formed above the N type equivalent resistance region;
a source electrode formed above the N+ type contact region;
an isolation dielectric region formed above the trench gate region;
a P+ type contact region penetrating the N+ type contact region, the N type equivalent resistance region and extending to the first P type region;
a second P type region between the gate dielectric layer and the N type equivalent resistance region;
a current diffusion region between the first P type region and the N− type drift region;
a doping concentration of the N type equivalent resistance region is greater than a doping concentration of the N− type drift region and less than a doping concentration that of the N+ type contact region;
a doping concentration of the second P type region is greater than the doping concentration of the N− type drift region;
a doping concentration of the current diffusion region is greater than the doping concentration of the N− type drift region and less than the doping concentration of the N+ type contact region.
